(19) United States
(12) Patent Application Publication
(10) Pub. No.: US 2025/0374489 A1
(43) Pub. Date: Dec. 4, 2025

(54) ROTATIONAL ECONOMIZER FOR AN EDGE DATA CENTER CONTAINER

(71) Applicant: International Business Machines Corporation, Armonk, NY (US)

(72) Inventors: John S. Werner, Fishkill, NY (US); Arkadiy O. Tsfasman, Wappingers Falls, NY (US); John Torok, Poughkeepsie, NY (US); Noah Singer, White Plains, NY (US); Dustin Demetriou, Hyde Park, NY (US)

(21) Appl. No.: 18/733,314

(22) Filed: Jun. 4, 2024

(51) Int. Cl. H05K 7/20

(52) U.S. Cl. CPC H05K 7/20745; H05K 7/202; H05K 7/20836

(57) ABSTRACT

An edge container with an integrated rotational economizer (ECIRE) includes a container, information technology (IT) equipment, an air conditioning unit (ACU), an economizer, where the container includes a cold aisle and a hot aisle. The ECIRE further includes the ACU configured to provide cooled air to the cold aisle of the container. The ECIRE further includes the IT equipment which, during operation, exhausts heated air to the hot aisle of the container. The economizer of the ECIRE further includes a first external rotational heat exchanger and an internal heat exchanger, where the first external rotational heat exchanger is positioned on an exterior surface of the container and the internal heat exchanger is positioned on an interior surface of the container.

### BACKGROUND

This disclosure relates generally to edge data center containers, and in particular to a rotational economizer for edge data center containers for reducing energy consumption for cooling information technology (IT) equipment.

Edge data center containers allow for rapid deployment of information technology (IT) equipment in a scalable manner based on computing resource requirements at a given location. Edge data center containers provide IT equipment for data processing typically found in a traditional data center, but at a location nearer to the end users to reduce latency and provide fast services. Due to the sensitivity of the IT equipment inside each of the edge data center containers, a mechanical based cooling system is provided to ensure the IT equipment operates in an environment with a set temperature and humidity range. Remote locations where edge data center containers are deployed typically have limited power sources for providing external electricity to power both, the IT equipment, and the cooling systems for the IT equipment.

### SUMMARY

A first aspect of an embodiment of the present invention discloses an apparatus for an edge container with an integrated rotational economizer (ECIRE), the apparatus comprising a container, information technology (IT) equipment, an air conditioning unit (ACU), an economizer, wherein the container includes a cold aisle and a hot aisle. The apparatus further includes the ACU configured to provide cooled air to the cold aisle of the container. The apparatus further includes the IT equipment configured to exhaust heated air to the hot aisle of the container. The apparatus further includes the economizer comprising a first external rotational heat exchanger and an internal heat exchanger, wherein the first external rotational heat exchanger is positioned on an exterior surface opposite the hot aisle of the container and the internal heat exchanger is positioned on an interior surface of the hot aisle of the container.

A second aspect of an embodiment of the present invention discloses a method for configuring an external rotational heat exchanger of an edge container with an integrated rotational economizer (ECIRE), the method comprising extracting external environmental condition data values. The method further includes extracting internal environmental condition data values for a hot aisle of the ECIRE. The method further includes adjusting the external rotational heat exchanger based on the extracted external environmental condition values and the extracted internal environmental condition values, wherein adjusting the external rotational heat exchanger includes rotating the external rotational heat exchanger relative to an internal heat exchanger.

### BRIEF DESCRIPTION OF THE SEVERAL VIEWS OF THE DRAWINGS

FIG. 1 depicts an edge container with an integrated rotational economizer, in accordance with an embodiment of the present invention.

FIG. 2 depicts simulated airflow within an edge container with an integrated rotational economizer, in accordance with an embodiment of the present invention.

FIG. 3A depicts an edge container with an integrated rotational economizer in a first configuration, in accordance with an embodiment of the present invention.

FIG. 3B depicts an overhead view of an edge container with an integrated rotational economizer in a first configuration, in accordance with an embodiment of the present invention.

FIG. 4A depicts an edge container with an integrated rotational economizer in a second configuration, in accordance with an embodiment of the present invention.

FIG. 4B depicts an overhead view of an edge container with an integrated rotational economizer in a second configuration, in accordance with an embodiment of the present invention.

FIG. 5 is a functional block diagram illustrating a computing environment, in accordance with an embodiment of the present invention.

FIG. 6 depicts a flowchart of an integrated rotational economizer program for configuring an external rotational heat exchanger for an edge container, in accordance with an embodiment of the present invention.

### DETAILED DESCRIPTION

According to an aspect of the invention, there is provided an apparatus for an edge container with an integrated rotational economizer (ECIRE), the apparatus includes a container, information technology (IT) equipment, an air conditioning unit (ACU), an economizer, wherein the container includes a cold aisle and a hot aisle. The apparatus further includes the ACU configured to provide cooled air to the cold aisle of the container and the IT equipment configured to exhaust heated air to the hot aisle of the container. The apparatus further includes the economizer comprising a first external rotational heat exchanger and an internal heat exchanger, where the first external rotational heat exchanger is positioned on an exterior surface opposite the hot aisle of the container and the internal heat exchanger is positioned on an interior surface of the hot aisle of the container. A technical advantage includes saving energy by reducing an output of an ACU through the utilization of the economizer with the first external rotational heat exchanger and the internal heat exchanger.

In embodiments, the first external rotational heat exchanger is positioned at least partially opposite the internal heat exchanger (feature A). A technical advantage includes an improved packaging of the economizer found in ECIRE.

In embodiments, feature A may be present. In embodiments, the first external rotational heat exchanger is configured to rotate relative to the internal heat exchanger (feature B). A technical advantage includes the first external rotational heat exchanger being able to rotate (i.e., configure) based on wind direction and cooling requirements for the IT equipment located in the ECIRE.

In embodiments, feature A and B may be present. In embodiments, the first external rotational heat exchanger includes a first plurality of heat fins, and the internal heat exchanger includes a second plurality of heat fins (feature C). A technical advantage includes the first plurality of fins and the second plurality of fins providing the exchanging of the cooled air with the heated air.

In embodiments, feature A, B, and C may be present. In embodiments, a first lower ring that provides a support for the first plurality of heat fins of the first external rotational heat exchanger and a first motor coupled to the first lower ring configured to rotate the first external rotational heat exchanger (feature D). A technical advantage includes a support structure for the plurality of fins that minimize manufacturing complexities of the first external rotational heat exchanger.

In embodiments, a first set of sensors positioned in the hot aisle on an interior of the container and a second set of sensors positioned on an exterior of the container (feature E). A technical advantage includes the first set and the second set of sensors providing the data for configuring the first external rotational heat exchanger.

In embodiments, feature E may be present. In embodiments, the first set of sensors and the second set of sensors are selected from the group consisting of: a temperature sensor, a pressure sensor, and a humidity sensor. A technical advantage includes utilizes a variety of sensors to ensure cooling requirements are met for the IT equipment in the ECIRE through the configuration of the first external rotational heat exchanger.

In embodiments, an aisle separator positioned between the hot aisle and the cold aisle of the container, wherein the aisle separator is configured to provide a seal between one or more of the hot aisle, the cold aisle, an exterior portion of the ACU, and an exterior portion of the IT equipment (feature F). A technical advantage includes the aisle separator providing a clear distinction between all the different volumes of ECIRE to maximum the efficiency of the ACU and the economizer.

In embodiments, feature F may be present. In embodiments, a plenum separator positioned between an IT equipment exhaust plenum and a mechanical air conditioner plenum of the container, where airflow exhausted from the IT equipment into the IT equipment exhaust plenum passes through a plurality of heat fins of the internal heat exchanger prior to entering the mechanical air conditioner plenum that feeds the airflow to an inlet of the ACU. A technical advantage includes the plenum separator providing a clear distinction between a volume with the heated air and a volume with the air cooled by the economizer.

In embodiments, feature A, B, C, and D may be present. In embodiments, the economizer further comprises a second external rotational heat exchanger (feature G). A technical advantage includes increase cooling capacity with the second external rotational heat exchanger to meet any cooling requirements of the IT equipment.

In embodiments, feature A, B, C, D, and G may be present. In embodiments, the second external rotational heat exchanger is positioned on the exterior surface of the container above the internal heat exchanger (feature H). A technical advantage includes the increased efficiency of positioning the second external rotational heat exchanger above the internal heat exchanger.

In embodiments, feature A, B, C, D, G, and H may be present. In embodiments, the second external rotational heat exchanger is configured to rotate relative to the internal heat exchanger (feature I). A technical advantage includes the second external rotational heat exchanger being able to rotate (i.e., configure) based on wind direction and cooling requirements for the IT equipment located in the ECIRE.

In embodiments, feature A, B, C, D, G, H, and I may be present. In embodiments, the first external rotational heat exchanger is configured to rotate independently of the second external rotational heat exchanger (feature J). A technical advantage includes the second external rotational heat exchanger being able to rotate independently from the first external rotational heat exchanger to allow for a greater range of configurability for specific cooling requirements.

In embodiments, feature A, B, C, D, G, H, I, and J may be present. In embodiments, the second external rotational heat exchanger includes a third plurality of heat fins (feature K). A technical advantage includes the third plurality of fins providing the additional exchanging of the cooled air with the heated air.

In embodiments, feature A, B, C, D, G, H, I, J, and K may be present. In embodiments, a second lower ring that provides a support for the third plurality of heat fins of the second external rotational heat exchanger and a second motor coupled to the second lower ring configured to rotate the second external rotational heat exchanger. A technical advantage includes a support structure for the plurality of fins that minimize manufacturing complexities of the second external rotational heat exchanger.

In embodiments, a data center infrastructure management device (DCIMD) within the container, wherein the DCIMD is configured to communicate to one or more of the ACU, the IT equipment, the first external rotational heat exchanger, a first set of sensors, and a second set of sensors (feature L). A technical advantage includes an auto-configurating system via the DCIMD for handling a configuration of the first external rotational heat exchanger based on the cooling requirements.

In embodiments, feature L may be present. In embodiments, the DCIMD is coupled to an interior surface of a sidewall of the container. A technical advantage included the DCIMD being securely positioned within the ECIRE, along with the IT equipment and the ACU.

According to an aspect of the invention, there is provided a method for configuring an external rotational heat exchanger of an edge container with an integrated rotational economizer (ECIRE), the method includes extracting external environmental condition data values. The method further includes extracting internal environmental condition data values for a hot aisle of the ECIRE. The method further includes adjusting the external rotational heat exchanger based on the extracted external environmental condition values and the extracted internal environmental condition values, where adjusting the external rotational heat exchanger includes rotating the external rotational heat exchanger relative to an internal heat exchanger. A technical advantage includes a method for saving energy by reducing an output of an ACU through the utilization of the economizer with the first external rotational heat exchanger and the internal heat exchanger.

In embodiments, adjusting the external rotational heat exchanger further includes rotating the external rotational heat exchanger relative to a wind direction passing through a plurality of fins of the external heat exchanger. A technical advantage includes maximizing energy savings by configuring the external rotational heat exchanger to provide maximum cooling via the economizer when external environmental conditions are better than internal environmental conditions.

In embodiments, adjusting the external rotational heat exchanger further includes rotating the external rotational heat exchanger such that a plurality of fins of the external rotational heat exchanger are perpendicular to a wind direction based on the extracted external environmental condition values being greater than the extracted internal environmental condition values. A technical advantage includes maximizing energy savings by configuring the external rotational heat exchanger to provide maximum cooling via the economizer when external environmental conditions are worse than internal environmental conditions.

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments. It is to be understood that the singular forms “a,” “an,” and “the” include plural referents unless the context clearly dictates otherwise. Thus, for example, reference to “a component surface” includes reference to one or more of such surfaces unless the context clearly dictates otherwise.

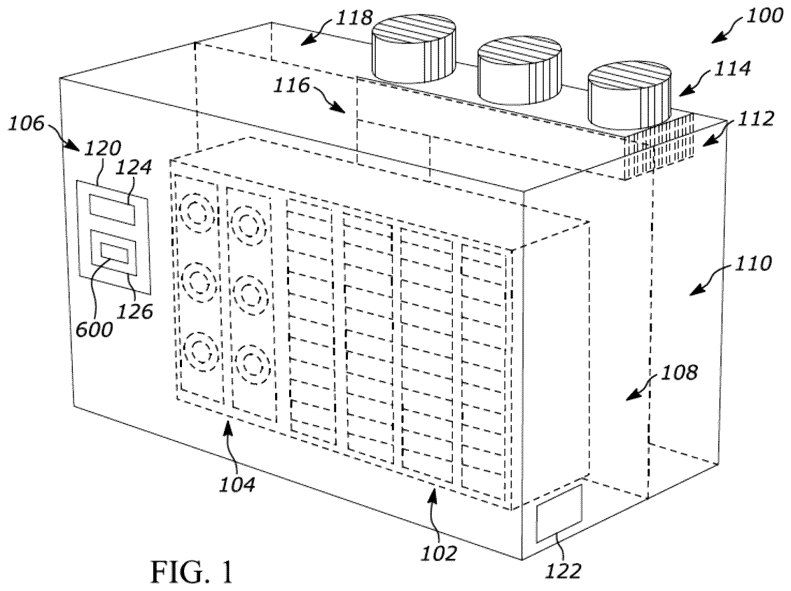

FIG. 1 depicts an edge container with an integrated rotational economizer, in accordance with an embodiment of the present invention. In this embodiment, edge container with an integrated rotational economizer (ECIRE) 100 includes various information technology (IT) equipment 102, air conditioning units (ACUs) 104, cold aisle 106, aisle separator 108, IT equipment exhaust plenum 110, internal heat exchanger 112, external rotational heat exchanger 114, plenum separator 116, mechanical air conditioner plenum 118, data center infrastructure management device (DCIMD) 120, and sensors 122.

IT equipment 102 includes multiple devices installed in a rack and/or enclosure such as, computers and associated peripheral devices, servers, networking switches, computer operating systems, utility/support software, communications hardware and software. During typical operational activity of IT equipment 102, heat is generated by the various devices installed in the racks and/or enclosures. To provide cooling to IT equipment 102, cool air enters a front portion of IT equipment 102 located in cold aisle 106 and cool air exits a rear portion of IT equipment 102 into IT equipment exhaust plenum 110. IT equipment exhaust plenum 110 is also referred to as a hot aisle in ECIRE 100.

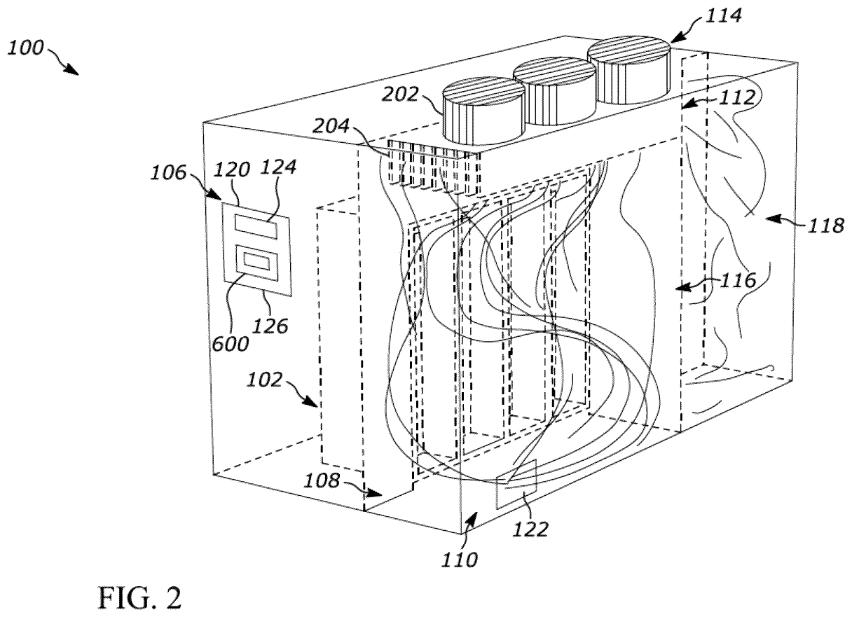

In this embodiment, ACUs 104 provide cool air utilizing multiple blowers and/or fans, along with a radiator and/or a refrigerant based cooling system to cold aisle 106. The combination of internal heat exchanger 112 and rotational external heat exchanger 114 are utilized to cool the hot air within IT equipment exhaust plenum 110 before circulating said air to ACUs 104, thus reducing an amount energy required for ACUs 104 to further cool the air prior to blowing the cool air into cold aisle 106. Aisle separator 108 is positioned between cold aisle 106 and IT equipment exhaust plenum 110, where aisle separator 108 creates a seal along a perimeter interior surface on four sides of ECIRE 100 and around a perimeter of a back end portion of both, IT equipment 102 and ACUs 104. Plenum separator 116 is configured to separate the airflow exhausted from IT equipment 102 from the airflow entering into mechanical air conditioner plenum 118 before entering one or more of the ACUs 104. The seal created by plenum separator 116 is discussed in further detail with regards to FIG. 2.

The combination of internal heat exchanger 112 and exterior rotational heat exchanger 114 represent an economizer portion of the cooling system for IT equipment 102. Internal heat exchanger 112 and external rotational heat exchanger 114 represent an add-on feature of the cooling system that provide an air-to-air heat exchanger that brings two air streams of different temperatures into thermal contact such as, cooler air external to ECIRE 100 and heated air from IT equipment 102 inside ECIRE 100. The thermal contact between the two air streams transfers the heat between the two environments. The heated air exhausted from IT equipment 102 is cooled by the cooler air external to ECIRE 100 prior to that air circulating back into mechanical air conditioner plenum 118 and fed into an inlet of ACUs 104.

In this embodiment, DCIMD 120 provides an oversight of operations of ECIRE 100. In particular, DCIMD 120 is utilized to discover, monitor, report, and visualize operations of ECIRE 100. DCIMD 120 is configured to improve the heat/cooling transfer between the internal and external environments of the edge container (i.e., ECIRE 100) thereby reducing the overall mechanical cooling power consumption as discussed further below. The internal environment, as used herein, refers to the environment within ECIRE 100 and the external environment, as used herein, refers to the environment outside ECIRE 100.

In one embodiment, DCIMD 120 includes a processor 124 and a memory 126. In one embodiment, integrated rotational economizer program 600 for improving the heat/cooling transfer between the internal and external environments of the edge container thereby reducing the overall mechanical cooling power consumption, may be loaded into memory 126. Examples of memory 126 include random access memory (RAM), dynamic RAM (DRAM), static RAM (SRAM), read-only memory (ROM), programmable ROM (PROM), erasable PROM (EPROM), electrically erasable PROM (EEPROM), an optical drive, and a solid-state drive. In one embodiment, processor 124 is configured to execute the instructions of a program, such as, integrated rotational economizer program 600.

In one embodiment, DCIMD 120 is a separate monitoring/computing device that is configured to communication with IT equipment 102, ACUs 104, external rotational heat exchanger 114, and sensors 122 utilizing a wireless network connection and/or a wired connection. In one embodiment, DCIMD 120 is located on a sidewall of ECIRE 100. In another embodiment, DCIMD 120 is located in IT equipment 102. In yet another embodiment, DCIMD 120 runs off of one or more devices of IT equipment 102.

Additionally, ECIRE 100 includes various sensors, such as sensors 122, to capture the environmental conditions, both internally and externally of ECIRE 100. Such environmental conditions include temperature, pressure, and humidity values. In one embodiment, sensors 122 are placed both internally and externally on a sidewall of ECIRE 100, including being attached to equipment, such as IT equipment 102, ACUs 104, internal heat exchanger 112 and exterior rotational heat exchanger 114. In other embodiments, sensors 122 are placed in multiple locations within cold aisle 106, IT exhaust plenum 110 (i.e., hot aisle), and/or mechanical air conditioner plenum 118. Furthermore, IT equipment 102 and ACUs 104 can include internal sensors that are utilized for monitoring environmental conditions for the devices themselves. In one embodiment, DCIMD 120 acquires such sensor data from sensor 122 using various software tools, including for example integrated rotational economizer program 600. Sensors 122 include, but are not limited to, pressure sensors, temperature sensors, and humidity sensors.

FIG. 2 depicts simulated airflow within an edge container with an integrated rotational economizer, in accordance with an embodiment of the present invention.

As illustrated, airflow exhausts from IT equipment 102 and is contained within IT exhaust plenum 110 (i.e., hot aisle) within ECIRE 100. In one embodiment, airflow is ducted through internal heat exchanger 112 due to the opening at the end of internal heat exchanger 112 above plenum separator 116 to mechanical air conditioner plenum 118.

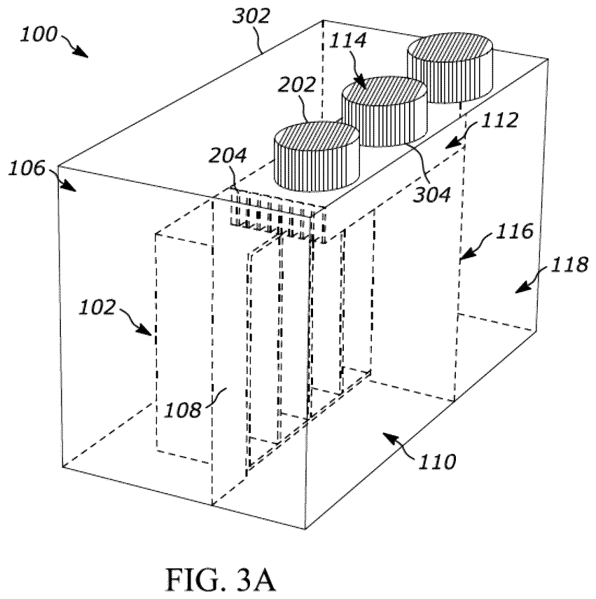

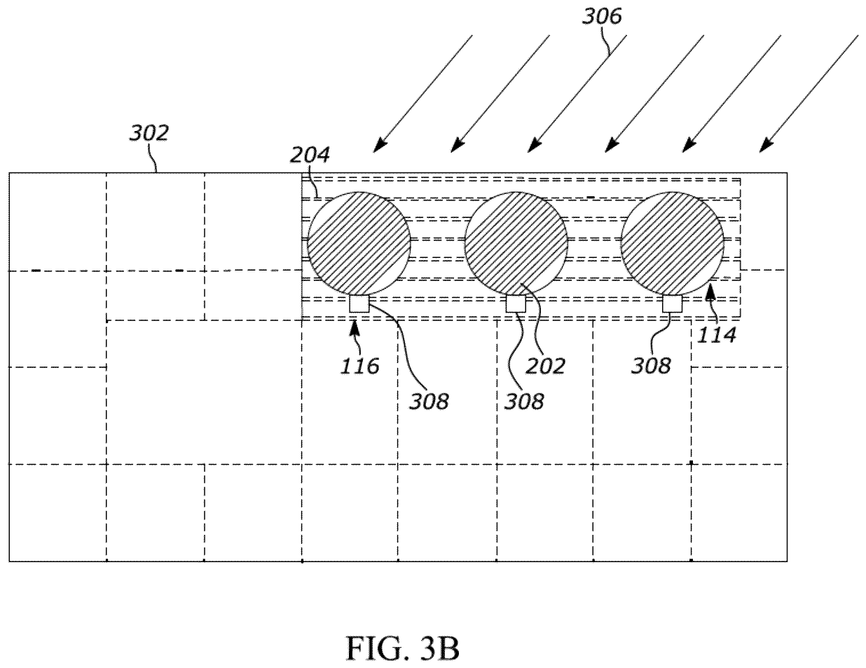

Heat from the air stream is transferred from ECIRE 100 to the outside environment via external rotational heat exchanger 114. External air flows through fins 202 of external rotational heat exchanger 114 allowing cool external air to transfer into ECIRE 100. The economizer, when in use, reaches an equilibrium temperature between the external air temperature and the temperature of the air inside IT equipment exhaust plenum 110. This allows for cooler air to be transferred to mechanical air conditioner plenum 118. Fins 202 of external rotational heat exchanger 114 are discussed below in further detail with regards to FIGS. 3A-3B. Fins 204 of internal heat exchanger 112 are also shown in FIG. 2. Fins 204 of internal heat exchanger 112 are discussed below in further detail with regards to FIG. 3A.

As external air flows over a top side of ECIRE 100, the external air removes more heat from IT equipment exhaust plenum 110. In some embodiments, one or more fans are coupled to a top and/or or bottom surface of fins 202 of each external rotational heat exchanger 114 on top of ECIRE 100 that directs external air through external rotational heat exchanger 114. In one example, one or more fans are coupled on top of fins 202 to direct the external air between fins 202. In another example, one or more fans are coupled beneath fins 202 but above a top side of internal heat exchanger 114, to pull the external air between fins 202. Similarly, one or more fans can be coupled to internal heat exchanger 112 to push or pull the heated air inside IT equipment exhaust plenum 110 between fins 204.

In one embodiment, airflow is exhausted into mechanical air conditioner plenum 118 before entering ACUs 104 for the remaining cooling needs. As illustrated in FIG. 2, the temperature within mechanical air conditioner plenum 118 is greatly reduced thereby ensuring that ACUs 104 draw less power leading to lower operation cost (reduced carbon footprint).

FIG. 3A depicts an edge container with an integrated rotational economizer in a first configuration, in accordance with an embodiment of the present invention. In this embodiment, each of the three external rotational heat exchangers 114 are rotated 30 degrees relative to internal heat exchanger 112. Specifically, fins 202 of external rotational heat exchanger 114 are rotated 30 degrees relative to fins 204 of internal heat exchanger 112. To maximize cooling efficiency, each of external rotational heat exchanger 114 are rotated, for example by integrated rotational economizer program 600, such that fins 202 of each external rotational heat exchanger 114 are in parallel with a wind direction. Though optimal cooling is provided when fins 202 of each external rotational heat exchanger 114 are in parallel with the wind direction, controlled cooling is provided by rotating each external rotational heat exchanger 114 such that fins 202 are positioned at other angles relative to the wind direction. For example, fins 202 of each external rotational heat exchanger 114 can be rotated perpendicular to the wind direction when an external air temperature is greater than a temperature of the air exhausted by IT equipment 102 such as, during light load conditions of IT equipment 102 and when ECIRE 100 is positioned in a high heat environment in direct sunlight. Each external rotation heat exchanger 114 can operate independently from one another, where a rotational angle is different for each of external rotation heat exchanger 114 (e.g., 30 degrees, 25 degrees, and 15 degrees, respectively).

Each external rotational heat exchanger 114 is mounted on an exterior surface of the top side 302 of ECIRE 100, where each external rotation heat exchanger 114 is rotatable in a clockwise or counterclockwise direction to align fins 202 in parallel with a current wind direction. Internal heat exchanger 112 is mounted to an inner surface of the top side 302 of ECIRE 100, opposite each external rotational heat exchanger 114. In other embodiments, internal heat exchanger 112 and/or external rotational heat exchangers 114 are mounted to one or more sidewalls of ECIRE 100. Each external rotational heat exchanger 114 can include multiple fins 202 for dissipating heat, where each of the multiple fins 202 are coupled to lower ring 304. In one embodiment, each valley between two fins 202 of each external rotational heat exchanger 114 includes a pass through to fins 204 of internal heat exchanger 112, where lower ring 304 provides the structure support for fins 204 at a circumference of each external rotational heat exchanger 114. In another embodiment, a pass through to fins 204 of internal heat exchanger 112 is not present between each valley of fins 202 of each external rotational heat exchanger 114, since a lower base plate is present on the bottom of fins 202 with a circumference defined by lower ring 304. A height of each fin from fins 202 and dimensions of each external rotational heat exchanger 114 is based on cooling requirements for the cooling system of ECIRE 100. It is to be noted that internal heat exchanger 112 is thermally coupled opposite to each external rotational heat exchanger 114 to facilitate heat transfer and is not limited to the embodiments discussed herein.

FIG. 3B depicts an overhead view of an edge container with an integrated rotational economizer in a first configuration, in accordance with an embodiment of the present invention. In the overhead view of ECIRE 100, fins 202 of each external rotational heat exchanger 114 are rotated 30 degrees relative to fins 204 of internal heat exchanger 112. Directional arrows 306 represents a direction for wind moving over top side 302 of ECIRE 100. In this embodiment, each external rotational heat exchanger 114 is rotated in a manner where fins 202 are in parallel with the direction for the wind moving over top side 302 of ECIRE 100 as illustrated with directional arrows 306. Each external rotational heat exchanger 114 is mechanically coupled to motor 308, where each motor 308 is configured to rotate each external rotational heat exchanger 114. Integrated rotational economizer program 600 operating on DCIMD 120 independently adjusts (i.e., rotates) each external rotational heat exchanger 114 utilizing each motor 308 such that fins 202 are in parallel with the wind direction.

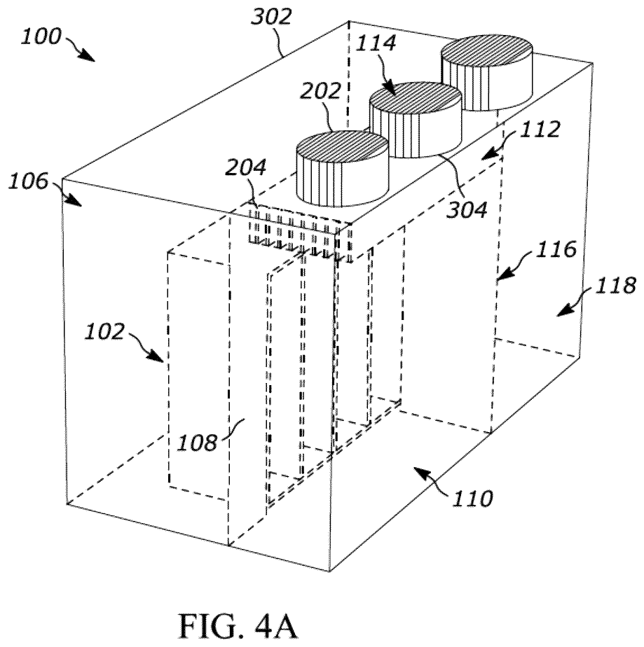

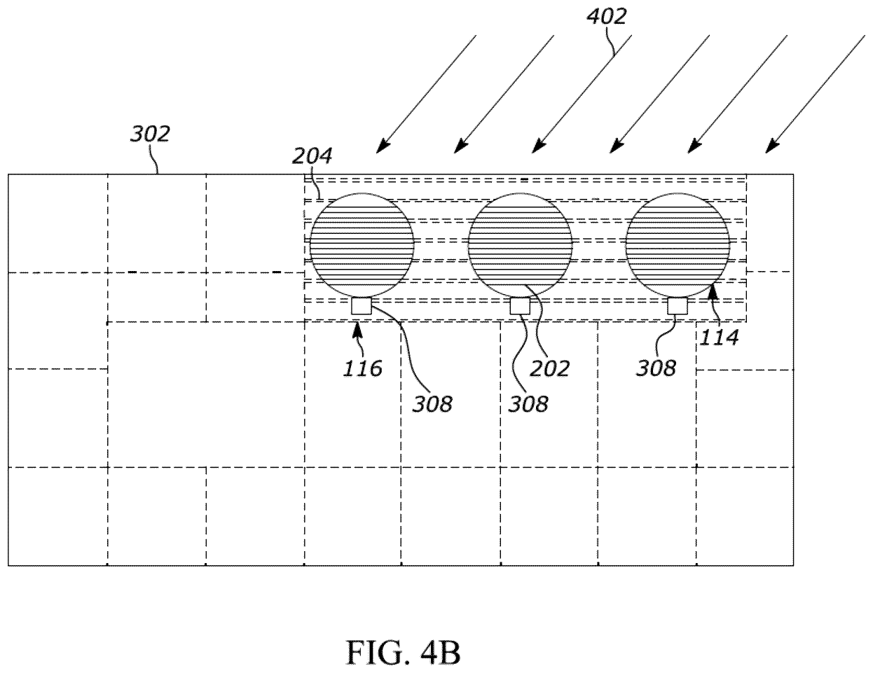

FIG. 4A depicts an edge container with an integrated rotational economizer in a second configuration, in accordance with an embodiment of the present invention. In this embodiment, each of the three external rotational heat exchangers 114 are rotated 0 degrees relative to internal heat exchanger 112. Specifically, fins 202 of external rotational heat exchanger 114 are rotated 45 degrees relative to the wind direction. Due to reduced cooling requirements each of external rotational heat exchanger 114 are rotated, for example by integrated rotational economizer program 600, such that fins 202 of each external rotational heat exchanger 114 are off axis to the wind direction. As previously discussed, each external rotation heat exchanger 114 can operate independently from one another, where a rotational angle is different for each of the external rotation heat exchangers 114. In other embodiments, when the wind speed is minimal or zero, an angle of each external rotational heat exchanger 114 remains unchanged from a previously established angle or integrated rotational economizer program 600 pre-emptively rotates each external rotational heat exchanger to an angle based on historical wind patterns or weather predictions.

FIG. 4B depicts an overhead view of an edge container with an integrated rotational economizer in a second configuration, in accordance with an embodiment of the present invention. In the overhead view of ECIRE 100, fins 202 of each external rotational heat exchanger 114 are rotated 45 degrees relative to the wind direction. Directional arrows 402 represent a direction for wind moving over top side 302 of ECIRE 100. In this embodiment, each external rotational heat exchanger 114 is rotated in a manner where fins 202 are off axis to the wind direction due to reduced cooling requirements as illustrated with directional arrows 402. As previously discussed with regards to FIG. 3B, each external rotational heat exchangers 114 is mechanically coupled to motor 308, where each motor 308 is configured to rotate each external rotational heat exchanger 114. Integrated rotational economizer program 600 operating on DCIMD 120 independently adjusts (i.e., rotates) each external rotational heat exchanger 114 utilizing each motor 308 such that fins 202 are in parallel with fins 204.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

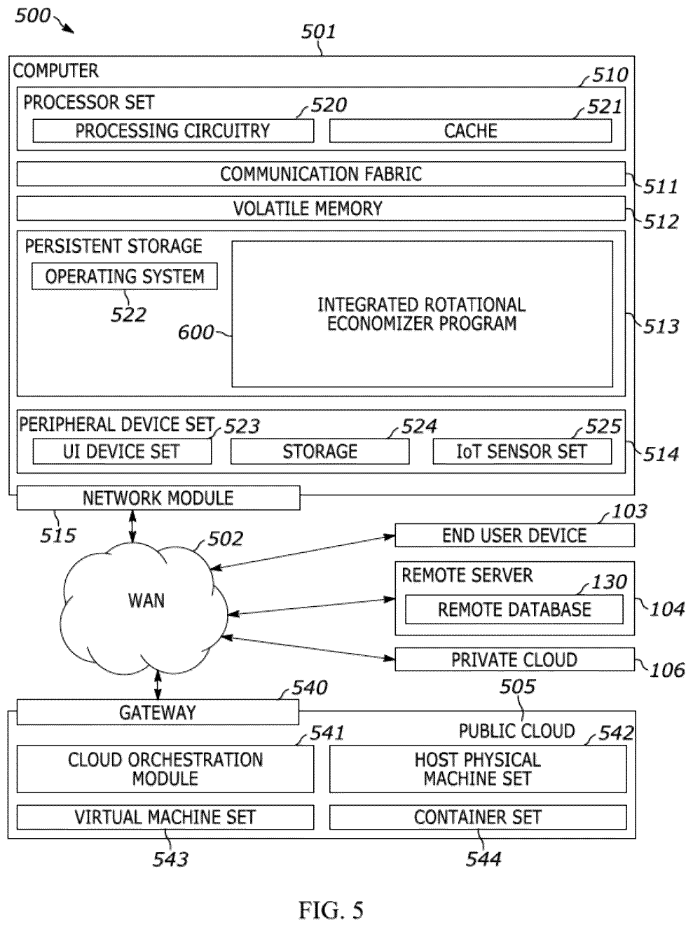

FIG. 5 is a functional block diagram illustrating a computing environment, generally designated 500, in accordance with one embodiment of the present invention. FIG. 5 provides only an illustration of one implementation and does not imply any limitations with regard to the environments in which different embodiments may be implemented. Many modifications to the depicted environment may be made by those skilled in the art without departing from the scope of the invention as recited by the claims.

Computing environment 500 contains an example of an environment for the execution of at least some of the computer code involved in performing the inventive methods, such as, integrated rotational economizer program 600. In addition to block 600, computing environment 500 includes, for example, computer 501, wide area network (WAN) 502, end user device (EUD) 503, remote server 504, public cloud 505, and private cloud 506. In this embodiment, computer 501 includes processor set 510 (including processing circuitry 520 and cache 521), communication fabric 511, volatile memory 512, persistent storage 513 (including operating system 522 and block 600, as identified above), peripheral device set 514 (including user interface (UI) device set 523, storage 524, and Internet of Things (IoT) sensor set 525), and network module 515. Remote server 504 includes remote database 530. Public cloud 505 includes gateway 540, cloud orchestration module 541, host physical machine set 542, virtual machine set 543, and container set 544.

Computer 501 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 530. As is well understood in the art of computer technology, and depending upon the technology, performance of a computer-implemented method may be distributed among multiple computers and/or between multiple locations. On the other hand, in this presentation of computing environment 500, detailed discussion is focused on a single computer, specifically computer 501, to keep the presentation as simple as possible. Computer 501 may be located in a cloud, even though it is not shown in a cloud in FIG. 5. On the other hand, computer 501 is not required to be in a cloud except to any extent as may be affirmatively indicated.

Processor set 510 includes one, or more, computer processors of any type now known or to be developed in the future. Processing circuitry 520 may be distributed over multiple packages, for example, multiple, coordinated integrated circuit chips. Processing circuitry 520 may implement multiple processor threads and/or multiple processor cores. Cache 521 is memory that is located in the processor chip package(s) and is typically used for data or code that should be available for rapid access by the threads or cores running on processor set 510. Cache memories are typically organized into multiple levels depending upon relative proximity to the processing circuitry. Alternatively, some, or all, of the cache for the processor set may be located “off chip.” In some computing environments, processor set 510 may be designed for working with qubits and performing quantum computing.

Computer readable program instructions are typically loaded onto computer 501 to cause a series of operational steps to be performed by processor set 510 of computer 501 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 521 and the other storage media discussed below. The program instructions, and associated data, are accessed by processor set 510 to control and direct performance of the inventive methods. In computing environment 500, at least some of the instructions for performing the inventive methods may be stored in block 600 in persistent storage 513.

Communication fabric 511 is the signal conduction path that allows the various components of computer 501 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 512 is any type of volatile memory now known or to be developed in the future. Examples include dynamic type random access memory (RAM) or static type RAM. Typically, volatile memory 512 is characterized by random access, but this is not required unless affirmatively indicated. In computer 501, the volatile memory 512 is located in a single package and is internal to computer 501, but, alternatively or additionally, the volatile memory may be distributed over multiple packages and/or located externally with respect to computer 501.

Persistent storage 513 is any form of non-volatile storage for computers that is now known or to be developed in the future. The non-volatility of this storage means that the stored data is maintained regardless of whether power is being supplied to computer 501 and/or directly to persistent storage 513. Persistent storage 513 may be a read only memory (ROM), but typically at least a portion of the persistent storage allows writing of data, deletion of data and re-writing of data. Some familiar forms of persistent storage include magnetic disks and solid state storage devices. Operating system 522 may take several forms, such as various known proprietary operating systems or open source Portable Operating System Interface-type operating systems that employ a kernel. The code included in block 600 typically includes at least some of the computer code involved in performing the inventive methods.

Peripheral device set 514 includes the set of peripheral devices of computer 501. Data communication connections between the peripheral devices and the other components of computer 501 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 523 may include components such as a display screen, speaker, microphone, wearable devices (such as goggles and smart watches), keyboard, mouse, printer, touchpad, game controllers, and haptic devices. Storage 524 is external storage, such as an external hard drive, or insertable storage, such as an SD card. Storage 524 may be persistent and/or volatile. In some embodiments, storage 524 may take the form of a quantum computing storage device for storing data in the form of qubits. In embodiments where computer 501 is required to have a large amount of storage (for example, where computer 501 locally stores and manages a large database) then this storage may be provided by peripheral storage devices designed for storing very large amounts of data, such as a storage area network (SAN) that is shared by multiple, geographically distributed computers. IoT sensor set 525 is made up of sensors that can be used in Internet of Things applications. For example, one sensor may be a thermometer and another sensor may be a motion detector.

Network module 515 is the collection of computer software, hardware, and firmware that allows computer 501 to communicate with other computers through WAN 502. Network module 515 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 515 are performed on the same physical hardware device. In other embodiments (for example, embodiments that utilize software-defined networking (SDN)), the control functions and the forwarding functions of network module 515 are performed on physically separate devices, such that the control functions manage several different network hardware devices. Computer readable program instructions for performing the inventive methods can typically be downloaded to computer 501 from an external computer or external storage device through a network adapter card or network interface included in network module 515.

WAN 502 is any wide area network (for example, the internet) capable of communicating computer data over non-local distances by any technology for communicating computer data, now known or to be developed in the future. In some embodiments, the WAN 502 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End User Device (EUD) 503 is any computer system that is used and controlled by an end user (for example, a customer of an enterprise that operates computer 501), and may take any of the forms discussed above in connection with computer 501. EUD 503 typically receives helpful and useful data from the operations of computer 501. For example, in a hypothetical case where computer 501 is designed to provide a recommendation to an end user, this recommendation would typically be communicated from network module 515 of computer 501 through WAN 502 to EUD 503. In this way, EUD 503 can display, or otherwise present, the recommendation to an end user. In some embodiments, EUD 503 may be a client device, such as thin client, heavy client, mainframe computer, desktop computer and so on.

Remote server 504 is any computer system that serves at least some data and/or functionality to computer 501. Remote server 504 may be controlled and used by the same entity that operates computer 501. Remote server 504 represents the machine(s) that collect and store helpful and useful data for use by other computers, such as computer 501. For example, in a hypothetical case where computer 501 is designed and programmed to provide a recommendation based on historical data, then this historical data may be provided to computer 501 from remote database 530 of remote server 504.

Public cloud 505 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 505 is performed by the computer hardware and/or software of cloud orchestration module 541. The computing resources provided by public cloud 505 are typically implemented by virtual computing environments that run on various computers making up the computers of host physical machine set 542, which is the universe of physical computers in and/or available to public cloud 505. The virtual computing environments (VCEs) typically take the form of virtual machines from virtual machine set 543 and/or containers from container set 544. It is understood that these VCEs may be stored as images and may be transferred among and between the various physical machine hosts, either as images or after instantiation of the VCE. Cloud orchestration module 541 manages the transfer and storage of images, deploys new instantiations of VCEs and manages active instantiations of VCE deployments. Gateway 540 is the collection of computer software, hardware, and firmware that allows public cloud 505 to communicate through WAN 502.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 506 is similar to public cloud 505, except that the computing resources are only available for use by a single enterprise. While private cloud 506 is depicted as being in communication with WAN 502, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 505 and private cloud 506 are both part of a larger hybrid cloud.

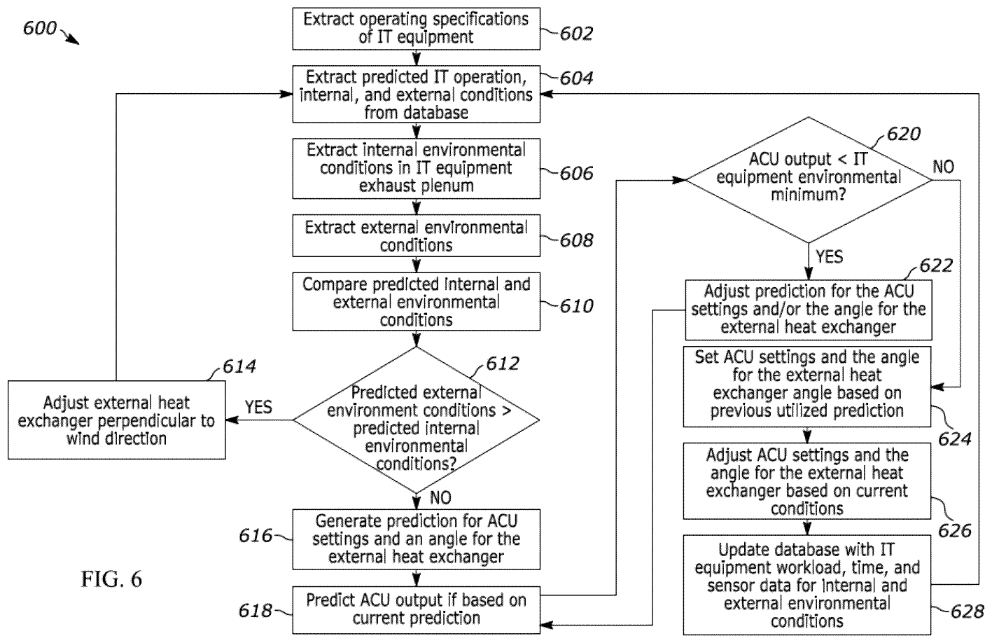

FIG. 6 depicts a flowchart of an integrated rotational economizer program for configuring an external rotational heat exchanger for an edge container, in accordance with an embodiment of the present invention.

Integrated rotational economizer program 600 extracts operating specifications of IT equipment (602). Integrated rotational economizer program 600 operating on DCIMD 120 extracts operating specifications of IT equipment 102 in ECIRE 100 to establish an overall operational range. In one example, equipment IT1 operates in a temperature range of 10° C.-35° C. and equipment IT2 operates in a temperature range of 5° C.-30° C. Integrated rotational economizer program 600 establishes an overall operating range of 10° C.-30° C. to satisfy the operating ranges of both, equipment IT1 and IT2. In other embodiments, integrated rotational economizer program 600 extracts specifications of IT equipment 102, along with the operating specification of ACUs 104, external rotational heat exchanger 114, and any other component of the cooling system operating in ECIRE 100 to provide an overall operational range. Integrated rotational economizer program 600 can also extract the maximum operational limit of a class or classes of IT equipment 102 in ECIRE 100. Operating specification of IT equipment 102 correlates to the internal environment conditions in which IT equipment 102 and can vary based on the temperature, pressure, and humidity.

In one embodiment, integrated rotational economizer program 600 extracts the operating specification of IT equipment 102, operating in ECIRE 100 from data stored directly on each device and/or piece of equipment. In another embodiment, integrated rotational economizer program 600 extracts the operating specification of IT equipment 102 operating in ECIRE 100 from data stored in a database that integrated rotational economizer program 600 maintains. Integrated rotational economizer program 600 can continuously update the database with the operating specification of IT equipment 102 operating in ECIRE 100 for any hardware and/or software revisions that might occur through an operational lifetime of each device and/or piece of equipment. In yet another embodiment, integrated rotational economizer program 600 extracts the operating specification of IT equipment 102 operating in ECIRE 100 from publicly available product specification sources (e.g., manufacturer website).

Integrated rotational economizer program 600 extracts predicted IT operation, internal, external environment conditions from the database (604). In one embodiment, integrated rotational economizer program 600 utilizes a database for storing various data, such as, historical operation, internal, and external environmental conditions where ECIRE 100 is deployed. For example, integrated rotational economizer program 600 can store workload information for IT equipment 102, time values and sensor data from sensors 122 for internal and external environmental conditions with respect to ECIRE 100. External environmental conditions can include historical temperature, pressure, and humidity values for an area in which ECIRE 100 is deployed. Integrated rotational economizer program 600 utilizes the stored data values for the external environmental conditions to predict weather conditions that ECIRE 100 might experience at the location. Alternatively, integrated rotational economizer program 600 can query an outside source (e.g., a weather provider) to extract weather predictions for the location that ECIRE 100 is deployed. In some embodiments, where historical workload information for IT equipment 102 is not available, integrated rotational economizer program 600 utilizes the historical internal and external environmental conditions, along with the cooling requirements of ACUs 104 to predict conditions ECIRE 100 can experience and how much cooling is required via adjustments to external rotational heat exchangers 114. In yet another embodiment, integrated rotational economizer program 600 monitors power utilization of IT equipment 102 to estimate workload and an amount of heat produced by the power utilization.

Integrated rotational economizer program 600 extracts internal environmental conditions in IT equipment exhaust plenum (606). In this embodiment, integrated rotational economizer program 600 extracts internal environmental conditions via sensors 122 in exhaust plenum 110 located behind IT equipment 102 in the hot aisle of ECIRE 100. Internal environmental conditions refer to temperature, pressure, and humidity values for an environment located inside of the confines of ECIRE 100. In some embodiments, integrated rotational economizer program 600 extracts internal environmental conditions via sensors 122 on IT equipment 102, ACUs 104, internal heat exchanger 112, within exhaust plenum 110, cold aisle 106, and mechanical air conditioning plenum 118.

Integrated rotational economizer program 600 extracts external environmental conditions (608). In this embodiment, integrated rotational economizer program 600 extracts external environmental conditions via sensors 122 on an exterior surface of ECIRE 100. External environmental conditions refer to temperature, pressure, and humidity values for an environment located outside of the confines of ECIRE 100.

Integrated rotational economizer program 600 compares predicted internal and external environmental conditions (610). In this embodiment, integrated rotational economizer program 600 compares the predicted internal environmental conditions of ECIRE 100 to the predicted external environmental conditions of ECIRE 100. Comparing the predicted internal and external environment conditions includes integrated rotational economizer program 600 comparing expected temperature, pressure, and humidity values from sensors 122 within IT equipment exhaust plenum 110 internal to ECIRE 100 to the temperature, pressure, and humidity values from sensors 122 external to ECIRE 100.

Integrated rotational economizer program 600 determines whether predicted external environmental conditions exceed predicted internal environmental conditions (decision 612). In the event integrated rotational economizer program 600 determines the predicted external environment conditions exceed the predicted internal environmental conditions (“yes” branch, decision 612), integrated rotational economizer program 600 adjusts the external heat exchanger perpendicular to the wind direction (614). In the event integrated rotational economizer program 600 determines the predicted external environment conditions do not exceed the predicted internal environmental conditions (“no” branch, decision 612), integrated rotational economizer program 600 generates a prediction for ACU settings and an angle for the external heat exchanger (616).

Integrated rotational economizer program 600 adjusts external heat exchanger perpendicular to the wind direction (614). Since the predicted external environmental conditions exceed the predicted internal environment conditions, integrated rotational economizer program 600 adjusts external rotational heat exchanger 114 on a top side of ECIRE 100 perpendicular to the wind direction. In one embodiment, integrated rotational economizer program 600 determines the predicted external environmental conditions including temperature, pressure, and/or humidity values that are worse than the predicted internal environmental conditions within exhaust plenum 110 for ECIRE 100. Therefore, integrated rotational economizer program 600 adjusts external rotational heat exchanger 114 perpendicular to the wind direction to avoid external air increasing the equilibrium temperature between external rotational heat exchangers 114 and internal heat exchanger 112 located inside ECIRE 100 which would lead to hotter air within mechanical air conditioning plenum 118 and increased power for ACU 104 to provide cooling to IT equipment 102. In this embodiment, perpendicular to the wind direction represents fins 202 of external rotational heat exchanger 114 being rotated 90 degrees to the wind direction. It is to be noted that perpendicular to the wind direction can include any angle greater than zero that is off axis to the wind direction (i.e., not parallel).

Integrated rotational economizer program 600 generates a prediction for ACU settings and an angle for the external heat exchanger (616). Integrated rotational economizer program 600 generates the prediction for ACU 104 settings based on a desired setpoint for the cumulative operational limits of all the equipment (e.g., IT equipment 102) located in ECIRE 100 with respect to the predicted external and internal environmental conditions. A setpoint, as used herein, refers to the value (e.g., 27° C.) of an environmental condition (e.g., temperature, pressure, humidity, etc.) that should not be exceeded when operating the equipment in question, where such a value may be adjusted based on readings of environmental conditions as discussed below. A desired setpoint, as used herein, refers to the setpoint that the equipment in question should not exceed while operating. In one embodiment, integrated rotational economizer program 600 initializes such a desired setpoint based on a percentage (e.g., 90%) of the maximum value of the cumulative operational range for all the equipment located in ECIRE 100. In another embodiment, integrated rotational economizer program 600 initializes a desired setpoint based on averaging the optimal setpoints for each equipment located in ECIRE 100 and ensures that value is within the cumulative operational range for all the equipment located in ECIRE 100. In yet another embodiment, a desired setpoint is set by the operator of IT equipment 102 located in ECIRE 100. In yet another embodiment, the desired setpoint is set to optimal temperature, pressure, and/or humidity values, where IT equipment 102 operates as efficiently as possible to prolong an expected life expectancy of the hardware.

Integrated rotational economizer program 600 also generates a prediction for an angle for each external rotational heat exchanger 114. Integrated rotational economizer program 600 generates the prediction for the angle of each external rotational heat exchanger 114 based on the predicted external environmental conditions and the predicted internal environmental conditions. In one example, integrated rotational economizer program 600 generates a prediction for three different angles for each external rotational heat exchanger 114 positioned on a top side of ECIRE 100. In an embodiment, integrated rotational economizer program 600 determines the predicted external environment conditions include sunny weather with a temperature of 25° C., a wind speed range of 5-10 knots with a wind direction of 270 degrees and the predicted internal temperature within mechanical air conditioning plenum 118 based on typical workload at the specified day and time is 35° C. (based on exhaust temperature from the IT equipment and internal heating due to factors such as the sun). Based on the predicted external environmental conditions, integrated rotational economizer program 600 predicts that a first external rotational heat exchanger 114 should be adjusted to 270 degrees with fins 202 in parallel with the wind direction, a second external rotational heat exchanger 114 should be adjusted to 225 degrees, and a third external rotational heat exchanger 114 should be adjusted to 180 degrees with fins 202 perpendicular (i.e., 90 degrees) to the wind direction.

Integrated rotational economizer program 600 predicts ACU output if based on current prediction (618). Integrated rotational economizer program 600 generates the prediction for ACU 104 settings based on a desired setpoint for the cumulative operational limits of all the equipment (e.g., IT equipment 102) located in ECIRE 100 with respect to current external and internal environmental conditions from sensors 122 and the current positions of external rotational heat exchangers 114 prior to rotating them to the calculated positions determined at 616.

Integrated rotational economizer program 600 determines if the predicted ACU output is less than IT equipment environmental minimum (decision 620). The predicted ACU output represents the predicted setpoint discussed above with regards to (616), which refers to the predicted setpoint of ACU 104. It is noted that the current ACU setpoint may not match the predicted setpoint. In the event integrated rotational economizer program 600 determines the predicted ACU output is less than IT equipment environmental minimum (“yes” branch, decision 620), integrated rotational economizer program 600 adjusts the prediction for the ACU settings and/or the angle for the external heat exchanger (622) and reverts to (618) to adjust the ACU output prediction until integrated rotational economizer program 600 determines the ACU output is less than the IT equipment environmental minimum (“no” branch, decision 620). In the event integrated rotational economizer program 600 determines the predicted ACU output is equal to or greater than IT equipment environmental minimum (“no” branch, decision 620), integrated rotational economizer program 600 sets ACU settings and the angle for the external heat exchanger based on a previously utilized prediction (624).

Integrated rotational economizer program 600 adjusts prediction for the ACU settings and/or the angle for the external heat exchanger (622). In this embodiment, integrated rotational economizer program 600 adjusts the prediction for ACU 104 settings based on a new predicted setpoint for the cumulative operational limits of all the equipment (e.g., IT equipment 102) located in ECIRE 100 with respect to the current external and internal environmental conditions. Adjusting the prediction for the ACU settings includes integrated rotational economizer program 600 increasing or decreasing a predicted output for ACUs 104 to provided optimal cooling to IT equipment 102. Adjusting the prediction for the angle for the external heat exchanger includes integrated rotational economizer program 600 predicted an altered an angle of at least one external rotational heat exchanger 114 positioned on the top side of ECIRE 100. In some embodiments integrated rotational economizer program 600 adjusts the prediction for ACU 104 settings, while maintaining the current angle for each external rotational heat exchanger 114. Alternatively, in some embodiments integrated rotational economizer program 600 adjusts an angle of one or more external rotational heat exchangers 114, while maintaining the current prediction for the ACU settings. Subsequent to the adjustments, integrated rotational economizer program 600 reverts to predicting ACU output based on current predictions (618).

Integrated rotational economizer program 600 sets ACU settings and the angle for the external heat exchanger angle based on previously generated prediction (624). In this embodiment, integrated rotational economizer program 600 sets ACU settings to the predicted ACU 104 settings based on the desired setpoint for the cumulative operational limits of all the equipment (e.g., IT equipment 102) located in ECIRE 100 with respect to the predicted external and internal environmental conditions, as discussed with respect to (616 or 622). Additionally, integrated rotational economizer program 600 sets the angle for each external rotation heat exchanger 114 based on the predicted angle, as discussed with respect to (616 or 622).

Integrated rotational economizer program 600 adjusts ACU settings and the angle for the external heat exchanger based on current conditions (626). In this embodiment, integrated rotational economizer program 600 adjusts ACU settings for ACUs 104 settings based on the desired setpoint for the cumulative operational limits of all the equipment (e.g., IT equipment 102) located in ECIRE 100 with respect to current external and internal environmental conditions. Additionally, integrated rotational economizer program 600 sets the angle for each external rotation heat exchanger 114 with respect to current external and internal environmental conditions.

Integrated rotational economizer program 600 updates the database with IT equipment workload, time, and sensor data for internal and external environmental conditions (628). As previously discussed, integrated rotational economizer program 600 utilizes the database for storing various data, such as, historical predicted external environmental conditions where ECIRE 100 is deployed. In this embodiment, integrated rotational economizer program 600 updates the database by storing workload information for IT equipment 102, time values, and sensor data from sensors 122 for internal and external environmental conditions with respect to ECIRE 100. External environmental conditions can include historical temperature, pressure, and humidity values for an area in which ECIRE 100 is deployed.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. An apparatus for an edge container with an integrated rotational economizer (ECIRE), the apparatus comprising:
a container, information technology (IT) equipment, an air conditioning unit (ACU), an economizer, wherein the container includes a cold aisle and a hot aisle;
the ACU configured to provide cooled air to the cold aisle of the container;
the IT equipment configured to exhaust heated air to the hot aisle of the container; and
the economizer comprising a first external rotational heat exchanger and an internal heat exchanger, wherein the first external rotational heat exchanger is positioned on an exterior surface opposite the hot aisle of the container and the internal heat exchanger is positioned on an interior surface of the hot aisle of the container.

2. The apparatus of claim 1, wherein the first external rotational heat exchanger is positioned at least partially opposite the internal heat exchanger.

3. The apparatus of claim 2, wherein the first external rotational heat exchanger is configured to rotate relative to the internal heat exchanger.

4. The apparatus of claim 3, wherein the first external rotational heat exchanger includes a first plurality of heat fins, and the internal heat exchanger includes a second plurality of heat fins.

5. The apparatus of claim 4, further comprising:
a first lower ring that provides a support for the first plurality of heat fins of the first external rotational heat exchanger; and
a first motor coupled to the first lower ring configured to rotate the first external rotational heat exchanger.

6. The apparatus of claim 1, further comprising:
a first set of sensors positioned in the hot aisle on an interior of the container; and
a second set of sensors positioned on an exterior of the container.

7. The apparatus of claim 6, wherein the first set of sensors and the second set of sensors are selected from the group consisting of: a temperature sensor, a pressure sensor, and a humidity sensor.

8. The apparatus of claim 1, further comprising:
an aisle separator positioned between the hot aisle and the cold aisle of the container, wherein the aisle separator is configured to provide a seal between one or more of the hot aisle, the cold aisle, an exterior portion of the ACU, and an exterior portion of the IT equipment.

9. The apparatus of claim 8, further comprising:
a plenum separator positioned between an IT equipment exhaust plenum and a mechanical air conditioner plenum of the container,
wherein airflow exhausted from the IT equipment into the IT equipment exhaust plenum passes through a plurality of heat fins of the internal heat exchanger prior to entering the mechanical air conditioner plenum that feeds the airflow to an inlet of the ACU.

10. The apparatus of claim 5, wherein the economizer further comprises a second external rotational heat exchanger.

11. The apparatus of claim 10, wherein the second external rotational heat exchanger is positioned on the exterior surface of the container above the internal heat exchanger.

12. The apparatus of claim 11, wherein the second external rotational heat exchanger is configured to rotate relative to the internal heat exchanger.

13. The apparatus of claim 12, wherein the first external rotational heat exchanger is configured to rotate independently of the second external rotational heat exchanger.

14. The apparatus of claim 13, wherein the second external rotational heat exchanger includes a third plurality of heat fins.

15. The apparatus of claim 14, further comprising:
a second lower ring that provides a support for the third plurality of heat fins of the second external rotational heat exchanger; and
a second motor coupled to the second lower ring configured to rotate the second external rotational heat exchanger.

16. The apparatus of claim 1, further comprising:
a data center infrastructure management device (DCIMD) within the container, wherein the DCIMD is configured to communicate to one or more of the ACU, the IT equipment, the first external rotational heat exchanger, a first set of sensors, and a second set of sensors.

17. The apparatus of claim 16, wherein the DCIMD is coupled to an interior surface of a sidewall of the container.

18. A method for configuring an external rotational heat exchanger of an edge container with an integrated rotational economizer (ECIRE), the method comprising:
extracting external environmental condition data values;
extracting internal environmental condition data values for a hot aisle of the ECIRE; and
adjusting the external rotational heat exchanger based on the extracted external environmental condition values and the extracted internal environmental condition values, wherein adjusting the external rotational heat exchanger includes rotating the external rotational heat exchanger relative to an internal heat exchanger.

19. The method of claim 18, wherein adjusting the external rotational heat exchanger further includes rotating the external rotational heat exchanger relative to a wind direction passing through a plurality of fins of the external heat exchanger.

20. The method of claim 18, wherein adjusting the external rotational heat exchanger further includes rotating the external rotational heat exchanger such that a plurality of fins of the external rotational heat exchanger are perpendicular to a wind direction based on the extracted external environmental condition values being greater than the extracted internal environmental condition values.
